(19) United States
(12) Patent Application Publication
(10) Pub. No.: US 2024/0154021 A1
(43) Pub. Date: May 9, 2024

(54) P-GAN HIGH-ELECTRON-MOBILITY TRANSISTOR

(71) Applicant: NATIONAL SUN YAT-SEN UNIVERSITY, Kaohsiung city (TW)

(72) Inventors: TING-CHANG CHANG, Kaohsiung City (TW); Wei-Chen Huang, Kaohsiung City (TW); Shih-Kai Lin, Kaohsiung City (TW); Yong-Ci Zhang, Kaohsiung City (TW); Sheng-Yao Chou, Kaohsiung City (TW); Chung-Wei Wu, Kaohsiung City (TW); Po-Hsun Chen, Kaohsiung City (TW)

(21) Appl. No.: 18/090,875

(22) Filed: Dec. 29, 2022

(30) Foreign Application Priority Data
Nov. 8, 2022 (TW) 111142614

(51) Int. Cl. H01L 29/66; H01L 21/02; H01L 29/20; H01L 29/778

(52) U.S. Cl. CPC H01L 29/66462; H01L 21/0228; H01L 21/02439; H01L 21/02521; H01L 29/2003; H01L 29/7786

(57) ABSTRACT

A p-GaN high-electron-mobility transistor (HEMT) includes a buffer layer stacked on a substrate, a channel layer stacked on the buffer layer, a supply layer stacked on the channel layer, a doped layer stacked on the supply layer, and a hydrogen barrier layer covering the supply layer and the doped layer. A source and a drain are electrically connected to the channel layer and the supply layer, respectively. A gate is located on the doped layer. The hydrogen barrier layer is doped with fluorine.

### CROSS REFERENCE TO RELATED APPLICATION

The application claims the benefit of Taiwan application serial No. 111142614, filed on Nov. 8, 2022, and the entire contents of which are incorporated herein by reference.

### BACKGROUND OF THE INVENTION

### 1. Field of the Invention

The present invention generally relates to an electronic element and, more particularly, to a p-GaN high-electron-mobility transistor (HEMT) that can block hydrogen diffusion to improve reliability of the element.

### 2. Description of the Related Art

With the rapid development of high-tech industries such as electric vehicles and 5G communications, electronic elements such as high-electron-mobility transistors (HEMTs) need to satisfy the requirements of high-power conversion, high-rate transmission, high bandwidth, and low energy consumption. Gallium nitride (GaN) has the characteristics of high breakdown voltage, high operation frequency, and good thermostability, and is an ideal semiconductor material for manufacturing HEMTs. Furthermore, a p-GaN HEMT formed by doping in the GaN layer is an enhancement-mode element, which is normally-off when no bias voltage is applied, to reduce the power consumption required for operating the element.

However, hydrogen diffuses easily during the manufacturing of conventional p-GaN HEMTs, leading to a reaction between hydrogen and dopants (such as magnesium) in the p-GaN layer. To be specific, originally, holes are provided by acceptors formed by doping with magnesium atoms to produce a p-type semiconductor material from GaN. However, with the diffusion of hydrogen in the manufacturing process, magnesium atoms react with hydrogen to form donors, which leads to a decrease in the quantity of acceptors, affecting the doping effect in the GaN layer, and resulting in current leakage in the side channel of the transistor and a reduced threshold voltage of the transistor element. Consequently, erroneous judgments may be made during the operation of the element. FIG. 1 is a schematic chart showing the relationship between the drain current and the gate voltage of a conventional p-GaN HEMT during operation. As the gate voltage increases, the drain current changes to show a curve with hump effect, and the resulting threshold voltage deviation causes the transistor to be incorrectly turned on/off.

In light of the above, it is necessary to improve the conventional p-GaN HEMTs.

### SUMMARY OF THE INVENTION

It is therefore an objective of the present invention to provide a p-GaN HEMT that can block hydrogen diffusion to maintain a doping effect of a p-GaN material.

It is another objective of the present invention to provide a p-GaN HEMT that can avoid current leakage in the side channel of the transistor.

It is still another objective of the present invention to provide a p-GaN HEMT that can improve a hump effect of the drain current.

It is yet still another objective of the present invention to provide a p-GaN HEMT that can avoid erroneous judgments in the threshold voltage and incorrect switching operation.

As used herein, the term “one”, “a” or “an” for describing the number of the elements and members of the present invention is used for convenience, provides the general meaning of the scope of the present invention, and should be interpreted to include one or at least one. Furthermore, unless explicitly indicated otherwise, the concept of a single component also includes the case of plural components.

In an aspect, a p-GaN high-electron-mobility transistor (HEMT) according to the present invention includes a buffer layer stacked on a substrate, a channel layer stacked on the buffer layer, a supply layer stacked on the channel layer, a doped layer stacked on the supply layer, and a hydrogen barrier layer covering the supply layer and the doped layer. A source and a drain are electrically connected to the channel layer and the supply layer, respectively. A gate is located on the doped layer. The hydrogen barrier layer is doped with fluorine.

Based on this, in the p-GaN HEMT of the present invention, the hydrogen barrier layer with fluorine doping covers the doped layer to block a reaction between hydrogen and the doped layer, which can avoid reduction of the doping effect of p-GaN, so that the problems of current leakage in the side channel of the transistor and the hump effect of the drain current can be resolved. In addition, the formation to the hydrogen barrier layer requires no change to the structure of the transistor, resulting in reductions of manufacturing difficulty and production cost.

In an example, the doped layer is a p-GaN layer formed by doping a GaN material with a dopant, and the dopant is any one of alkaline earth metals. Thus, the threshold voltage of the transistor can be increased by doping to change the transistor into an enhancement-mode element, thereby improving the switching performance of the element.

In an example, a material of the hydrogen barrier layer includes fluorine-doped silicon dioxide, fluorine-doped gallium oxide, fluorine-doped silicon nitride, or fluorine-doped aluminum oxide. Thus, fluorine can easily bond with elements of other compounds, and the resulting bonding vacancies can bond with hydrogen, thereby blocking hydrogen diffusion.

In an example, a fluorine-containing gas is introduced in a process of growing the hydrogen barrier layer through deposition. Thus, the growth of the hydrogen barrier layer requires neither addition nor modification to transistor structure, thereby reducing production cost.

In an example, the fluorine-containing gas is carbon tetrafluoride, trifluoromethane, difluoromethane, or fluoromethane. Thus, the fluorine-containing gas can free fluorine during deposition to bond with other compounds, thereby providing the source of fluorine for doping.

In an example, the deposition is atomic layer deposition, physical vapor deposition, or chemical vapor deposition. Thus, the fluorine-containing gas can be introduced during deposition, without changing other manufacturing steps and elements, thereby simplifying the process.

In an example, the fluorine-containing gas is introduced at a flow rate of 5-100 cm³/min. Thus, the concentration of fluorine for doping can be adjusted according to the size and use requirements of the transistor, thereby providing sufficient fluorine atoms to block hydrogen diffusion.

### BRIEF DESCRIPTION OF THE DRAWINGS

The present invention will become more fully understood from the detailed description given hereinafter and the accompanying drawings which are given by way of illustration only, and thus are not limitative of the present invention, and wherein:

FIG. 1 is a schematic chart showing the relationship between the drain current and the gate voltage of a conventional p-GaN HEMT.

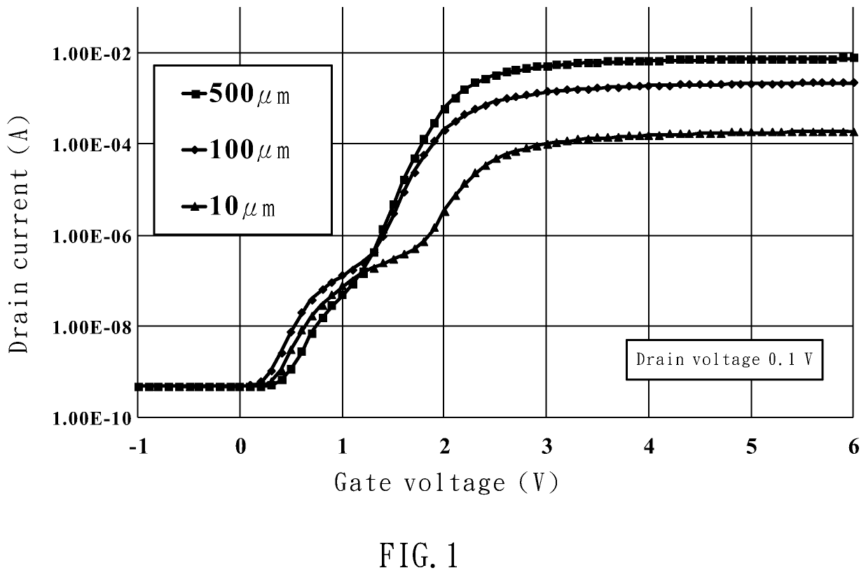

FIG. 2 is a schematic diagram of a stacked structure according to a preferred embodiment of the present invention.

FIG. 3 is a schematic chart showing the relationship between the drain current and the gate voltage of transistors in the related art and in a preferred embodiment of the present invention.

In the various figures of the drawings, the same numerals designate the same or similar parts, and the description thereof will be omitted. Furthermore, when the terms “front”, “rear”, “left”, “right”, “up (top)”, “down (bottom)”, “inner”, “outer”, “side”, and similar terms are used hereinafter, it should be understood that these terms have reference only to the structure shown in the drawings as it would appear to a person viewing the drawings, and are utilized only to facilitate describing the invention.

### DETAILED DESCRIPTION OF THE INVENTION

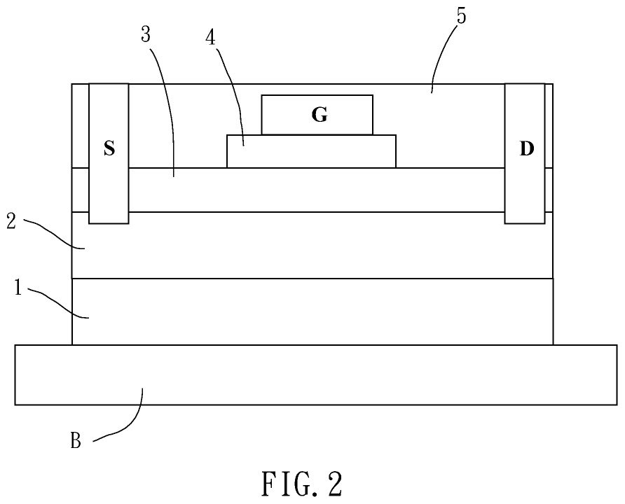

FIG. 2 shows a preferred embodiment of the p-GaN HEMT of the present invention. The p-GaN HEMT includes a buffer layer 1, a channel layer 2, a supply layer 3, a doped layer 4, and a hydrogen barrier layer 5. The buffer layer 1 is located on a substrate B. The channel layer 2, the supply layer 3, and the doped layer 4 are sequentially stacked on the buffer layer 1 from bottom to top. The hydrogen barrier layer 5 covers the supply layer 3 and the doped layer 4.

The buffer layer 1 is located between the substrate B and the transistor structure, and is configured to avoid defects in the interface caused by heterostructure difference between the substrate B and a semiconductor material (such as GaN used in the present invention). To be specific, a material of the substrate B typically includes silicon, which has a large difference in lattice constant and coefficient of thermal expansion from GaN, easily leading to increase of defect density and warpage. Therefore, the buffer layer 1 is first grown on the substrate B, and then transistor materials such as metals, insulators, and semiconductors are formed on the buffer layer 1, which can cure defects to improve element reliability. In this embodiment, a material of the buffer layer 1 includes AlGaN and GaN.

The channel layer 2 and the supply layer 3 are made of materials with different band gaps. A two-dimensional electron gas (2DEG) is formed at the heterojunction between the channel layer 2 and the supply layer 3, which can provide an electron channel for electrons to move rapidly, so that the transistor element has good high-frequency characteristics. In addition, a source S and a drain D are respectively located at both ends of the electron channel and are electrically connected to the channel layer 2 and the supply layer 3, respectively, so that electrons between the source S and the drain D efficiently move between the channel layer 2 and the supply layer 3 through the electron channel. In this embodiment, a material of the channel layer 2 includes GaN, and a material of the supply layer 3 includes AlGaN.

The doped layer 4 is formed by introducing a dopant to an intrinsic semiconductor during deposition. The intrinsic semiconductor is GaN, and the dopant may be an alkaline earth (group IIA) metal, to make the doped layer 4 a p-GaN layer. In addition, a gate G is located on the doped layer 4. The on/off of the electron channel can be switched by controlling the strength of the electric field applied to the gate G, to adjust the output current of the drain D.

The hydrogen barrier layer 5 is configured to block hydrogen diffusion to the doped layer 4 during the manufacturing of the transistor, which can avoid hydrogen from reacting with the dopant to reduce the doping effect of the doped layer 4. A material of the hydrogen barrier layer 5 may include fluorine-doped silicon dioxide (SiO₂:F), fluorine-doped gallium oxide (Ga₂O₃:F), fluorine-doped silicon nitride (Si₃N₄:F), or fluorine-doped aluminum oxide (Al₂O₃:F). During the growth of the hydrogen barrier layer by atomic layer deposition (ALD), physical vapor deposition (PVD), or chemical vapor deposition (CVD), a precursor of the fluorine-containing gas such as CF₄, CHF₃, CH₂F₂, or CH₃F is introduced to cover the doped layer 4 with the hydrogen barrier layer 5 with fluorine doping. The fluorine-containing gas may be introduced at a flow rate of 5-100 cm³/min.

As fluorine has the highest electronegativity of all the elements, fluorine atoms are more likely to bond with elements (such as silicon) of other compounds in the hydrogen barrier layer 5, and the bonding vacancies (such as oxygen or nitrogen vacancies) in the compounds occupied by fluorine can be used to capture hydrogen atoms, so as to isolate hydrogen in the hydrogen barrier layer 5 and prevent hydrogen from diffusing into the doped layer 4.

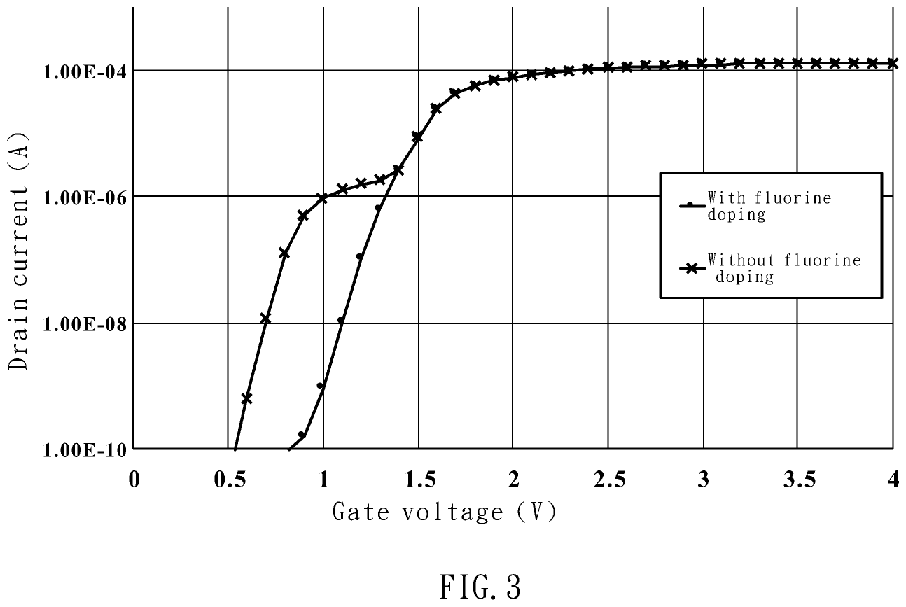

FIG. 3 is a schematic chart showing the relationship between the drain current and the gate voltage of the p-GaN HEMT with fluorine doping in the present invention and the conventional p-GaN HEMT without fluorine doping. It can be learned from the curves that the drain current of the conventional p-GaN HEMT without fluorine doping exhibits a significant hump at the gate voltage of 1-2 V, which is likely to lead to an erroneous judgment of the position of the threshold voltage of the transistor. On the contrary, the hump effect is not present in the drain current of the p-GaN HEMT with fluorine doping in the present invention, from which the position of the threshold voltage can be easily determined.

In addition, in the manufacturing process of the p-GaN HEMT of the present invention, it is only necessary to introduce the fluorine-containing gas during the growth of the hydrogen barrier layer 5, without additional process requirements such as modification to the photomask and change to the transistor structure, which can simplify the process and reduce production costs.

Based on the above, in the p-GaN HEMT of the present invention, the hydrogen barrier layer with fluorine doping covers the doped layer to block a reaction between hydrogen and the doped layer, which can avoid reduction of the doping effect of p-GaN, so that the problems of current leakage in the side channel of the transistor and the hump effect of the drain current can be resolved. In addition, the formation to the hydrogen barrier layer requires no change to the structure of the transistor, resulting in reductions of manufacturing difficulty and production cost.

Although the invention has been described in detail with reference to its presently preferable embodiments, it will be understood by one of ordinary skill in the art that various modifications can be made without departing from the spirit and the scope of the invention, as set forth in the appended claims. Further, if the above-mentioned several embodiments can be combined, the present invention includes any implementation aspects of combinations thereof.

What is claimed is:

1. A p-GaN high-electron-mobility transistor, comprising:
a buffer layer stacked on a substrate;
a channel layer stacked on the buffer layer;
a supply layer stacked on the channel layer, wherein a source and a drain are electrically connected to the channel layer and the supply layer, respectively;
a doped layer stacked on the supply layer, wherein a gate is located on the doped layer; and
a hydrogen barrier layer covering the supply layer and the doped layer, wherein the hydrogen barrier layer is doped with fluorine.

2. The p-GaN high-electron-mobility transistor as claimed in claim 1, wherein the doped layer is a p-GaN layer formed by doping a GaN material with a dopant, and wherein the dopant is any one of alkaline earth metals.

3. The p-GaN high-electron-mobility transistor as claimed in claim 1, wherein a material of the hydrogen barrier layer includes fluorine-doped silicon dioxide, fluorine-doped gallium oxide, fluorine-doped silicon nitride, or fluorine-doped aluminum oxide.

4. The p-GaN high-electron-mobility transistor as claimed in claim 1, wherein a fluorine-containing gas is introduced in a process of growing the hydrogen barrier layer through deposition.

5. The p-GaN high-electron-mobility transistor as claimed in claim 4, wherein the fluorine-containing gas is carbon tetrafluoride, trifluoromethane, difluoromethane, or fluoromethane.

6. The p-GaN high-electron-mobility transistor as claimed in claim 4, wherein the deposition is atomic layer deposition, physical vapor deposition, or chemical vapor deposition.

7. The p-GaN high-electron-mobility transistor as claimed in claim 4, wherein the fluorine-containing gas is introduced at a flow rate of 5-100 cm³/min.
